(19) United States
(12) Patent Application Publication
(10) Pub. No.: US 2020/0176485 A1
(43) Pub. Date: Jun. 4, 2020

(54) ARRAY SUBSTRATE AND METHOD FOR MANUFACTURING THE SAME AND DISPLAY DEVICE

(71) Applicant: Wuhan China Star Optoelectronics Semiconductor Display Technology Co., Ltd., Wuhan (CN)

(72) Inventor: Yi JIANG, Wuhan (CN)

(21) Appl. No.: 16/332,360

(22) PCT Filed: Jan. 2, 2019
(86) PCT No.: PCT/CN2019/070021

§ 371 Date: Mar. 12, 2019

(30) Foreign Application Priority Data
Dec. 3, 2018 (CN) 201811466935.3

(51) Int. Cl. H01L 27/12; H01L 29/786; H01L 21/02; H01L 29/66

(52) U.S. Cl. CPC H01L 27/1222; H01L 29/78675; H01L 27/1248; H01L 29/78633; H01L 27/1218; H01L 27/1262; H01L 21/02532; H01L 21/02595; H01L 29/66757; H01L 21/02664; H01L 27/127

(57) ABSTRACT

The present disclosure provides an array substrate, a method for manufacturing the array substrate, and a display device. A low temperature polysilicon includes a base layer, a low temperature polysilicon layer, a gate insulating layer, gate electrodes, and an interlayer dielectric layer. The low temperature polysilicon layer is formed on the base layer. The gate insulating layer is formed on the low temperature polysilicon layer. The gate electrodes are formed on the gate insulating layer. The interlayer dielectric layer covers the gate electrodes and the gate insulating layer. In the method for manufacturing the array substrate, hydriding the low temperature polysilicon layer is arranged before coating the interlayer dielectric layer; the interlayer dielectric layer is formed with a high temperature following the hydriding process to eliminate rapid thermal annealing activation, to simplify the industry procedure, and to save the energy consumption and the cost.

### BACKGROUND OF INVENTION

### Field of Invention

The present invention relates to a display field, and particularly to an array substrate and a method for manufacturing the array substrate, and a display device.

### Description of Prior Art

At the present, thin film transistors (TFTs) are important driving components of liquid crystal displays (LCDs) and active matrix organic light-emitting diodes (AMOLEDs) that directly relates to display performance of a flat panel display device.

Thin film transistors include a variety of structures, and a variety of materials are used to manufacturing the corresponding structure. Low temperature polysilicon (LTPS) is an excellent one among them. The low temperature polysilicon is a branch of polycrystalline silicon (p-Si). High electron mobility of the low temperature polysilicon effectively reduces a device area of the thin-film transistor, improves an aperture ratio of pixels, increases panel display brightness and reduces power consumption of integration, and greatly reduces panel production cost. As the existing display device of the flat panel display, some advantages, such as a high resolution, a fast response speed, high brightness, a high aperture ratio, and a low energy consumption, etc. are obtained by applying a low temperature polysilicon technology, and the low temperature polysilicon can be fabricated at a low temperature condition and can also be used for making complementary metal-oxide semiconductor (CMOS) circuits, so it has become a current technology in the display field.

One weakness of a prior-art method intervertebral disc buying for manufacturing an array substrate is, an inter level dielectric (ILD) is usually made of a double layer structure of silicon oxide (SiO) and silicon nitride (SiN), the low temperature polysilicon is deposited in the subsequent manufacturing process and destroyed as a dangling bond is formed. Therefore, a one-step hydrogenation step is usually applied in the manufacturing process of the array substrate, that is, after deposition of the inter level dielectric is completed, rapid thermal annealing (RTA) is adopted to diffuse hydrogen ions (H+) formed by a Si—H bond of a silicon nitride layer in the inter level dielectric through high temperature diffusion, and repairs it into the dangling bond in the low temperature polysilicon layer. The manufacturing method requires a silicon nitride inter level dielectric to perform hydrogenation repairing dangling bonds, which increases the cost and is a complicated manufacturing process.

### SUMMARY OF INVENTION

An object of the present invention is to provide an array substrate, a method for manufacturing the array substrate, and a display device to solve the complication and high cost during a process of manufacturing of the array substrate of the prior art.

For the above-mentioned objective, the present invention provides an array substrate, wherein includes a base layer, a low temperature polysilicon layer, a gate electrode insulating layer, a plurality of gate electrodes and an interlayer dielectric layer. The low temperature polysilicon layer is formed on the base layer. The gate electrode insulating layer is formed on the low temperature polysilicon layer. The gate electrodes are formed on the gate electrode insulating layer. The interlayer dielectric layer is formed on the gate electrodes and the gate electrode insulating layer

Further, the low temperature polysilicon layer includes a plurality of source electrode regions and a plurality of drain electrode regions. The array substrate further includes a plurality of contacting holes, a plurality of source electrodes and a plurality of drain electrodes;

the contacting holes extends from the interlayer dielectric layer through the gate electrode insulating layer to the low temperature polysilicon layer, one of the contacting holes corresponds to one of the source electrode regions, and another one of the contacting holes corresponds to one of the drain electrode regions; and

the source electrodes and the drain electrodes are formed on the interlayer dielectric layer, wherein the source electrodes are correspondingly connected to the source electrode regions by the ones of the contacting holes, and the drain electrodes are correspondingly connected to the drain electrode regions by another ones of the contacting holes.

Further, the base layer includes a base, a shielding layer, a first buffer layer, a second buffer layer. The shielding layer formed on the base, wherein the shielding layer corresponds to the low temperature polysilicon layer. The first buffer layer is formed on the shielding layer. The second buffer layer are formed the first buffer layer, wherein the low temperature polysilicon layer is formed on the second buffer layer.

Further, the interlayer dielectric layer is made of a single layer of silicon oxide.

The present invention further provides a method for manufacturing an array substrate, including:

forming a base layer;

forming a low temperature polysilicon layer on the base layer;

coating a gate electrode insulating layer on the base layer, wherein the gate electrode insulating layer covers the low temperature polysilicon layer;

forming a plurality of gate electrodes on the gate electrode insulating layer;

hydriding the low temperature polysilicon layer; and

forming an interlayer dielectric layer on the gate electrode insulating layer, wherein the interlayer dielectric layer covers the gate electrodes.

Further, the step of hydriding the low temperature polysilicon layer includes: adding hydrogen plasma with a temperature of 300° C.-500° C.; applying an electric field, and dissociating the hydrogen plasma into hydrogen ions by the electric field to make the hydrogen ions to diffuse into the low temperature polysilicon layer.

Further, in the step of forming the low temperature polysilicon layer, the lower temperature polysilicon includes a plurality of source electrode regions and a plurality of drain electrode regions, employing an n-type doping or a p-type doping process in the source electrode regions and the drain electrode regions.

Further, after the step of forming the low temperature polysilicon layer on the base layer the method further includes: defining a plurality of contacting holes, the contacting holes extends from the interlayer dielectric layer through the gate electrode insulating layer to the low temperature polysilicon layer; forming a plurality of source electrodes and a plurality of drain electrodes on the interlayer dielectric layer, and the source electrodes are correspondingly connected to the source electrode regions by the ones of the contacting holes, and the drain electrodes are correspondingly connected to the drain electrode regions by another ones of the contacting holes.

Further, the step of forming the base layer includes:

providing a base; forming a shielding layer on the base, wherein the shielding layer corresponds to the low temperature polysilicon layer; forming a first buffer layer on the base, wherein the first buffer layer covers the shielding layer; and forming a second buffer layer on the first buffer layer, wherein the low temperature polysilicon layer is formed on the second buffer layer.

The present invention also provides a display device includes the array substrate of the above.

The benefit of the present invention is:

An array substrate of the present invention employs an interlayer dielectric layer made of a single layer structure to reduce a thickness of the array substrate, so the manufacturing process is simplified and the cost is saved.

A method for manufacturing the array substrate of the present invention hydrides the low temperature polysilicon layer before the step of coating the interlayer dielectric layer, coating the interlayer dielectric layer with a high temperature after the step of hydriding, the rapid thermal annealing activation process is eliminated and the industry procedure is cut down, and the energy consumption and the cost is saved.

A display device of the present invention shows advantages of a high resolution, a fast response speed, a high brightness, a high aperture ratio, and a low energy consumption, etc.

### BRIEF DESCRIPTION OF DRAWINGS

FIG. 1 is a structural schematic view of a layer structure of an array substrate of one exemplary embodiment of the present invention.

FIG. 2 is a flowchart of a method for manufacturing an array substrate of one exemplary embodiment of the present invention.

FIG. 3 is a flowchart of a method for manufacturing a base layer of one exemplary embodiment of the present invention.

FIG. 4 is a structural schematic view of a layer structure of a display device of one exemplary embodiment of the present invention.

The components of the drawings are as follows:
A display device 1000;
An array substrate 100; a color film substrate 200;
A base layer 10;
A substrate 11; a shielding layer 12;
A first buffer layer 13; a second buffer layer 14;
A low temperature polysilicon layer 20;
A source electrode region 21; a drain electrode region 22;
A gate electrode insulating layer 30; a gate electrode 40;
An interlayer dielectric layer 50; a contacting hole 60;
A source electrode 70; a drain electrode 80.

### DETAILED DESCRIPTION OF PREFERRED EMBODIMENTS

The following description of every embodiment with reference to the accompanying drawings is used to exemplify a specific embodiment, which may be carried out in the present invention. The embodiments completely introduce the present disclosure for person skilled in the art, which makes technology content clear and understand. The present disclosure embodies through different types of the embodiment. The protection range of the present disclosure is not limited in the embodiment of the present disclosure.

In the drawings, the components having similar structures are denoted by the same numerals. The structures and the components have similar function can use similar numerals to express. Thickness and size of each of the components of the drawings is randomly shown, the present disclosure does not limit thickness and size of each of the components of the drawings. In order to make the drawings clear, the thicknesses of some components in the drawings properly are increased.

The following description of the embodiments with reference to the accompanying drawings is used to illustrate particular embodiments of the present invention. The directional terms referred in the present invention, such as “upper”, “lower”, “front”, “back”, “left”, “right”, “inner”, “outer”, “side”, etc. are only directions with regard to the accompanying drawings. Therefore, the directional terms used for describing and illustrating the present invention are not intended to limit the present invention. In addition, terms such as “first”, “second” and “third” are used herein for purposes of description and are not intended to indicate or imply relative importance or significance.

When a certain component is described as being on/above/over another component, the component may be placed directly on the other component, or there may also be an intermediate component, the component is placed on/above/over the intermediate component, and the intermediate component is placed on/above/over the other component. When a component is described as being disposed on or connected to another component, it may understood that the component is directly disposed on or connected to the other component, or the component is disposed on or connected to the other component via an intermediate component.

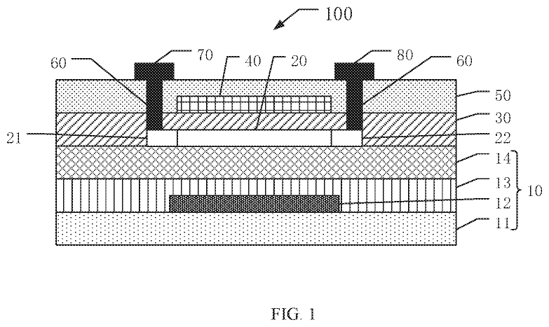

Please refer to FIG. 1, one embodiment of the present embodiment provides an array substrate 100 including a base layer 10, a low temperature polysilicon layer 20, a gate electrode insulating layer 30, a plurality of gate electrodes 40, and an interlayer dielectric layer 50.

The base layer 10 includes a substrate 11, a shielding layer 12, a first buffer layer 13 and a second buffer layer 14.

The substrate 11 is an insulating substrate, the insulating substrate is made of insulating materials, such as glass or quartz, and aim to protect an integral structure of the array substrate 100.

The shielding layer 12 are formed on the substrate 11, the shielding layer 12 corresponds to the low temperature polysilicon layer 20, in the present embodiment, an orthographic projection center of the shielding layer 12 placed on the substrate 11 is coincided with the orthographic projection center of the low temperature polysilicon layer 20 placed on the substrate 11 to shield the low temperature polysilicon layer 20 to prevent the light leakage. The shielding layer 12 is made of a light-proof material, the light-proof material is metal or amorphous silicon, but there is not limited for the material of the shielding layer 12 in the present exemplary embodiment, and the other materials are also applicable.

The first buffer layer 13 is made of one of silicon nitride, silicon oxide or silicon oxynitride, which is formed on the substrate 11 and covers the shielding layer 12. The second buffer layer 14 is made of one of silicon nitride, silicon oxide or silicon oxynitride, which is formed on the first buffer layer 13. The first buffer layer 13 and the second buffer layer 14 are applied to protect the low temperature polysilicon layer 20 to reduce the damage caused by the movement and oscillation of the low-temperature polysilicon layer 20, and further to prevent metal ion in the substrate 11 to diffuse into the array substrate 100, especially to diffuse into the low-temperature polysilicon layer 20, thereby affecting electrical properties of the array substrate 100.

The low temperature polysilicon layer 20 formed on the first buffer layer 13 includes a plurality of source electrode regions 21 and a plurality of drain electrode regions 22. The source electrode regions 21 and the drain electrode regions 22 are prepared by ion doping technology, that is an n-type heavy doping process with a same n-type ion which is employed to process the source electrode regions 21 and the drain electrode regions 22 or a p-type heavy doping process with a same p-type ion which is employed to process the source electrode regions 21 and the drain electrode regions 22. The source electrode regions 21 and the drain electrode regions 22 are employed by the doping process to reduce contact resistance defined between source electrodes 70 and the low temperature polysilicon layer 20 and between drain electrodes 80 and low temperature polysilicon layer 20, to reduce leakage current of the array substrate 10 and to improve electrical performance of the array substrate 100.

The gate electrode insulating layer 30 is formed on the low temperature polysilicon layer 20 and is formed by coating an insulating material, the insulating material can be made of one of silicon oxide, silicon nitride, or silicon oxynitride. The gate insulating material is configured to protect and isolate the low temperature polysilicon layer 20.

The gate electrodes 40 are formed on the gate electrode insulating layer 30, and the gate electrodes 40 correspond to the low temperature polysilicon layer 20. The gate electrodes 40 are made of a conductive material, the conductive material can be made of tungsten, chromium, aluminum, and copper, etc. The gate electrodes 40 are configured to generate an electric field through a voltage, thereby changing a thickness of the conductive channel to control the current of the source electrodes 70 and the drain electrodes 80.

The interlayer dielectric layer 50 is formed on the gate electrodes 40 and the gate insulating layer 30 and is prepared by chemical vapor deposition. The interlayer dielectric layer 50 is employed by a dielectric isolating technique, the interlayer dielectric layer is made of an insulating dielectric material, the insulating dielectric material can be made of one of silicon oxide, silicon nitride, and silicon oxynitride. The interlayer dielectric layer is configured to isolate metal wiring, for example, the gate electrodes 40, the source electrodes 70, and the drain electrodes 80.

In the present exemplary embodiment, the array substrate 100 further includes a plurality of contacting holes 60, the plurality of source electrodes 70, and the plurality of drain electrodes 80.

The contacting holes 60 extend from the interlayer dielectric layer 50 through the gate electrode insulating layer 30 to the low temperature polysilicon layer 20, one of the contacting holes 60 corresponds to one of the source electrode regions 21, and another one of the contacting holes 60 corresponds to one of the drain electrode regions 22.

The source electrodes 70 and the drain electrodes 80 are formed on the interlayer dielectric layer 50. The source electrodes 70 and the drain electrodes 80 can be prepared by a metal patterning process. Each of the source electrodes 70 is correspondingly connected to the source electrode regions 21 by one of the contacting holes 60, and each of the drain electrodes 80 is correspondingly connected to the drain electrode regions 22 by one of the contacting holes 60.

In the present exemplary embodiment, the array substrate is made of a single layered interlayer dielectric layer structure to reduce a thickness of the array substrate 100, to simplify the manufacturing process, and to save the cost.

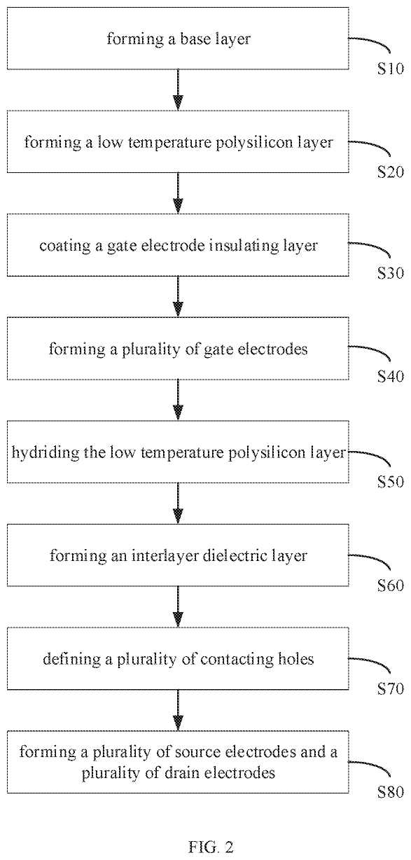

The present exemplary embodiment further provides a method for manufacturing an array substrate, as shown in FIG. 2, and the method for manufacturing the array substrate includes the following steps:

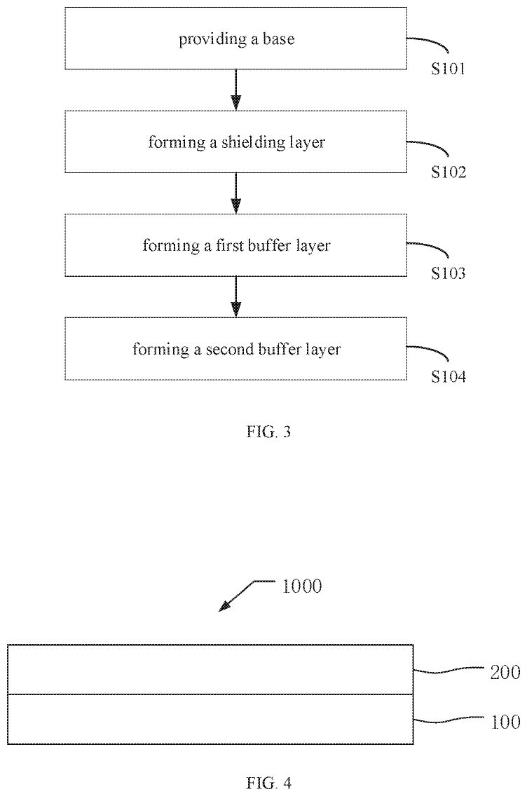

Step S10, forming a base layer 10; the step S10 includes step S101-S104, the manufacturing process is as shown in FIG. 3.

Step S101, providing a base 11: an insulating substrate is provided, the insulating substrate is an insulating material, and the insulating material is made of glass or quartz, etc.

Step S102, forming a shielding layer 12: the shielding layer 12 is formed on the base 11 by a chemical vapor deposition process, and then the shielding layer 12 is defined to a specify shape by an exposure or development process. The shielding layer is made by a light-proof material, and the light-proof material can be made of metal or amorphous silicon, etc., but there is not limited for the material of the shielding layer 12 in the present exemplary embodiment, and the other materials are also applicable.

Step S103, forming a first buffer layer 13: the first buffer layer 13 is formed on the base 11, and the first buffer layer 13 covers the shielding layer 12. The first buffer layer 13 is made of silicon nitride.

Step S104, forming a second buffer layer 14: the second buffer layer 14 is coated on the first buffer layer 13, and the second buffer layer 14 is made of silicon oxide.

Step 20, forming a low temperature polysilicon layer 20 on the base layer 10: the low temperature polysilicon layer 20 is formed on the base layer 10 and corresponds to the shielding layer 12. The low temperature polysilicon layer 20 includes a plurality of source electrode regions 21 and a plurality of drain electrode regions 22. The source electrode regions 21 and the drain electrode regions 22 are prepared by an ion doping technology, a same type of ions are employed to process the source electrode regions 21 and the drain electrode regions 22, and the ion is n-type ion doping or p-type ion doping based on the doping process.

Step S30, coating a gate electrode insulating layer 30 on the base layer 10: the gate electrode insulating layer 30 is coated on the base layer 10 by employing an insulating material, and the insulating material can be made of silicon oxide. The gate electrode insulating layer 30 covers the low temperature polysilicon layer 20.

Step S40, forming a plurality of gate electrodes 40 on the gate electrode insulating layer 30: the gate electrodes 40 are formed on the gate electrode insulating layer 30 by employing a conductive material, the gate electrodes 40 corresponds to the low temperature polysilicon layer 20, and then the gate electrodes 40 are patterned by an etching process. The conductive material is made of tungsten, chromium, aluminum, and copper, etc.

Step S50, hydriding the low temperature polysilicon layer 20: hydrogen plasma is added with a temperature of 300° C.-500° C. An electric field is applied, and the hydrogen plasma is dissociated into hydrogen ions by the electric field to make the hydrogen ions to diffuse into the low temperature polysilicon layer 20. The intensity of the electric field is set according to an actual manufacturing process.

Step S60, forming an interlayer dielectric layer 50 on the gate electrode insulating layer 30: on the gate insulating layer 30, the single layered interlayer dielectric layer 50 is formed by coating silicon oxide by chemical vapor deposition on the gate insulating layer 30, and the interlayer dielectric layer 50 covers the gate electrodes 40.

Step S70, defining a plurality of contacting holes 60: the contacting holes are defined by an exposure process or a development process, the contacting holes 60 extend from the interlayer dielectric layer 50 through the gate electrode insulating layer 30 to the low temperature polysilicon layer 20. One of the contacting holes 60 corresponds to the source electrode regions 21, another contacting holes 60 correspond to the drain electrode regions 22.

Step S80, forming a plurality of source electrodes 70 and a plurality of drain electrodes 80 on the interlayer dielectric layer 50: a metal conductive material is coated on the interlayer dielectric layer 50 and in the contacting holes 60, and a metal layer is formed on the interlayer dielectric layer 50. The metal layer is patterned by an etching process or a photoetching process to form the source electrodes 70 and the drain electrodes 80, the source electrodes 70 are connected to the source electrode regions 21, and the drain electrodes 80 are connected to the drain electrode regions 22.

In the present exemplary embodiment, the step of hydriding the low temperature polysilicon layer 20 is changed before the step of coating the interlayer dielectric layer 50 to eliminate a rapid thermal annealing activation process of the prior art to simply an industry procedure, and to save the energy consumption and the cost.

Referring to FIG. 4, the present exemplary embodiment provides a display device 1000, which includes panels of the array substrate 100 and a color film substrate 200 etc., the color film substrate 200 faces the array substrate 100. The display device 1000 of the present exemplary embodiment further includes other structures, such as polarizer and frame etc., and the essentials of the present exemplary embodiment are all in the array substrate 100, therefore, the structure of the middle frame and polarizer are not described in detail.

The display device 1000 of the present exemplary embodiment employs the array substrate 100 of the present invention with advantages of a high resolution, a fast response speed, high brightness, a high aperture ratio, and low energy consumption, etc.

In the present exemplary embodiment, the step of hydriding the low temperature polysilicon layer 20 is changed before the step of coating the interlayer dielectric layer 50 and the interlayer dielectric layer 50 is formed with a high temperature following the step of the hydriding process to eliminate the rapid thermal annealing activation process of the prior art, to simply the industry procedure, and to save the energy consumption. And, just one interlayer dielectric layer 50 is formed in the present exemplary embodiment to decrease the thickness of the array substrate 100, after the display device 1000 is fabricated by the array substrate 100, the thickness of the display device 1000 is decreased.

The present disclosure is illustrated hereinabove with reference to the specific embodiments, which are only examples of the principle and use of the present disclosure. Those skilled in the art can make amendments to the embodiments disclosed herein or provide other arrangements without departing from the spirit and scope of the present disclosure. The technical feature described in one embodiment can also be used in other embodiments.

What is claimed is:

1. An array substrate, comprising:
a base layer;
a low temperature polysilicon layer formed on the base layer;
a gate electrode insulating layer formed on the low temperature polysilicon layer;
a plurality of gate electrodes formed on the gate electrode insulating layer; and
an interlayer dielectric layer formed on the gate electrodes and the gate electrode insulating layer.

2. The array substrate of claim 1, wherein the low temperature polysilicon layer comprises a plurality of source electrode regions and a plurality of drain electrode regions;
the array substrate further comprises:
a plurality of contacting holes, wherein the contacting holes extends from the interlayer dielectric layer through the gate electrode insulating layer to the low temperature polysilicon layer, one of the contacting holes corresponds to one of the source electrode regions, and another one of the contacting hole corresponds to one of the drain electrode regions; and
a plurality of source electrodes and a plurality of drain electrodes formed on the interlayer dielectric layer, wherein the source electrodes are correspondingly connected to the source electrode regions by the ones of the contacting holes, and the drain electrodes are correspondingly connected to the drain electrode regions by another ones of the contacting holes.

3. The array substrate of claim 1, wherein the base layer comprises:
a base;
a shielding layer formed on the base, wherein the shielding layer corresponds to the low temperature poly silicon layer;
a first buffer layer formed on the shielding layer; and
a second buffer layer formed the first buffer layer, wherein the low temperature polysilicon layer is formed on the second buffer layer.

4. The array substrate of claim 1, wherein the interlayer dielectric layer is made of a single layer of silicon oxide.

5. A method for manufacturing an array substrate, comprising:
forming a base layer;
forming a low temperature polysilicon layer on the base layer;
coating a gate electrode insulating layer on the base layer, wherein the gate electrode insulating layer covers the low temperature polysilicon layer;
forming a plurality of gate electrodes on the gate electrode insulating layer;
hydriding the low temperature polysilicon layer; and
forming an interlayer dielectric layer on the gate electrode insulating layer, wherein the interlayer dielectric layer covers the gate electrodes.

6. The method for manufacturing the array substrate of claim 5, wherein the step of hydriding the low temperature polysilicon layer comprises:
adding hydrogen plasma with a temperature of 300° C.-500° C.;
applying an electric field, and dissociating the hydrogen plasma into hydrogen ions by the electric field to make the hydrogen ions to diffuse into the low temperature polysilicon layer.

7. The method for manufacturing the array substrate of claim 6, wherein in the step of forming the low temperature polysilicon layer, the lower temperature polysilicon comprises a plurality of source electrode regions and a plurality of drain electrode regions, and employing an n-type doping or a p-type doping process in the source electrode regions and the drain electrode regions.

8. The method for manufacturing the array substrate of claim 6, wherein after the step of forming the low temperature polysilicon layer on the base layer the method further comprises:
defining a plurality of contacting holes, wherein the contacting holes extend from the interlayer dielectric layer through the gate electrode insulating layer to the low temperature polysilicon layer;
forming a plurality of source electrodes and a plurality of drain electrodes on the interlayer dielectric layer, wherein the source electrodes are correspondingly connected to the source electrode regions by ones of the contacting holes, and the drain electrodes are correspondingly connected to the drain electrode regions by another ones of the contacting holes.

9. The method for manufacturing the array substrate of claim 6, wherein the step of forming the base layer comprises:
providing a base;
forming a shielding layer on the base, wherein the shielding layer corresponds to the low temperature poly silicon layer;
forming a first buffer layer on the base, wherein the first buffer layer covers the shielding layer; and
forming a second buffer layer on the first buffer layer, wherein the low temperature polysilicon layer is formed on the second buffer layer.

10. A display device comprises the array substrate of claim 1.
